(19) United States
(12) Patent Application Publication
(10) Pub. No.: US 2024/0093379 A1
(43) Pub. Date: Mar. 21, 2024

(54) METAL MACHINED COMPONENT, COMPONENT-MOUNTED MODULE EQUIPPED WITH SAME, AND METHOD FOR MANUFACTURING SAME

(71) Applicant: UNITED PRECISION TECHNOLOGIES CO., LTD., TOKYO (JP)

(72) Inventors: FUMINORI MITSUHASHI, TOKYO (JP); TAKUNORI MATSUBARA, TOKYO (JP)

(73) Assignee: UNITED PRECISION TECHNOLOGIES CO., LTD., TOKYO (JP)

(21) Appl. No.: 17/767,431

(22) PCT Filed: Oct. 11, 2020
(86) PCT No.: PCT/JP2020/037837

§ 371 Date: Apr. 7, 2022

(30) Foreign Application Priority Data
Oct. 11, 2019 (JP) JP2019-188115

(51) Int. Cl. C23F 1/02

(52) U.S. Cl. CPC C23F 1/02

(57) ABSTRACT

To treat a corner of an etched metal machined article by a method other than polishing. A method includes: forming a protective layer 200 on each of a front surface 120 and a back surface 140 of a metal plate 100 while a side surface 160 of the metal plate 100 is exposed; cutting out a precursor 300 of a component to be manufactured from the metal plate 100 on which the protective layer 200 is formed; etching the precursor 300 without removing the protective layer 200; chamfering a corner between the front surface 120 and the side surface 160 and a corner between the back surface 140 and the side surface 160 of the etched precursor 300 by an electrical or chemical treatment; and removing the protective layer 200 from the chamfered precursor 300.

### TECHNICAL FIELD

The present invention relates to a metal machined component, a component-mounted module equipped with same, and a method for manufacturing same, particularly to a metal machined component related to a precision machine or the like, a component-mounted module equipped with same, and a method for manufacturing same.

### BACKGROUND ART

Patent Literature 1 discloses a method for manufacturing a metal machined article, the method including: sequentially bonding a masking sheet having an adhesive layer on a corrosion-resistant film to a metal component under heating of at least a surface of the metal component by a pressure-bonding method at a linear pressure of 1 to 30 kg/cm to form a coating film on a non-processed part of the metal component, and then etching the coating film with a corrosive liquid to remove a surface of a non-coated part.

### CITATION LIST

### Patent Literature

Patent Literature 1: JP 1993-239670 A

### SUMMARY OF INVENTION

### Technical Problem

However, in the invention disclosed in Patent Literature 1, the etched metal machined article may have a sharp corner, and as a result, the corner may damage a peripheral member, or cut or the like the peripheral member in the worst case.

On the other hand, even if it is attempted to chamfer the corner of the etched metal machined article by polishing or the like, chamfering may be difficult because many metal machined articles are fine, and chamfering may be practically impossible in some cases.

Therefore, an object of the present invention is to treat a corner of an etched metal machined article by a method other than polishing.

### Solution to Problem

In order to solve the above problem, a metal machined component of the present invention has an inclined surface having no processing mark at a corner between a front surface and a side surface and at a corner between a back surface and the side surface.

The side surface and the inclined surface may have a surface roughness different from the front surface and the back surface. The side surface may have a protruding cross section.

A component-mounted module of the present invention includes the above-described metal machined component.

Furthermore, a method for manufacturing a metal machined component according to the present invention includes:
forming a protective layer on each of a front surface and a back surface of a metal plate while a side surface of the metal plate is exposed;
cutting out a precursor of a component to be manufactured from the metal plate on which the protective layer is formed;
etching the cut-out precursor without removing the protective layer;
chamfering a corner between the front surface and the side surface and a corner between the back surface and the side surface of the etched precursor by an electrical or chemical treatment; and
removing the protective layer from the chamfered precursor.

### DESCRIPTION OF EMBODIMENTS

Hereinafter, an embodiment of the present invention will be described with reference to the drawings.

FIG. 1 is a schematic manufacturing process diagram of a metal machined component according to an embodiment of the present invention.

As illustrated in FIG. 1A, first, a substrate 100 to be a base material of a metal machined component is prepared (step S1). For convenience, an upper surface of the substrate 100 in FIG. 1A is referred to as a front surface 120, a lower surface thereof is referred to as a back surface 140, and front, back, left, and right surfaces thereof are referred to as side surfaces 160.

The substrate 100 only needs to have a size corresponding to a metal machined component to be manufactured. For example, the substrate 100 having a thickness of about 25 μm to 300 μm is prepared if the metal machined component is small like a component-mounted module to be mounted on a precision machine. The length and width of the substrate 100 only need to be increased as the number of metal machined components to be manufactured from one substrate 100 increases.

The substrate 100 may be made of, for example, copper, iron, aluminum, or an alloy thereof (for example, stainless steel), but is not limited thereto. In addition, which metal is adopted only needs to be determined according to a use and the like.

For example, when it is desired to manufacture a contact pin used for semiconductor wafer inspection or the like, the substrate 100 can be made of copper. When it is desired to manufacture a mesh-like metal plate of a speaker or a rectifying plate having a mesh portion, the substrate 100 can be made of stainless steel. Furthermore, when it is desired to manufacture a heat sink, the substrate 100 can be made of aluminum.

As illustrated in FIG. 1B, next, a protective layer 200 is formed on each of the front surface 120 and the back surface 140 of the substrate 100 prepared in step S1 (step S2). At this time, the protective layer 200 is not formed on each of the side surfaces 160 of the substrate 100. The protective layer 200 is preferably made of a material that is not dissolved by an etching solution used for etching in step S4 described later.

Here, it is not necessary that the protective layer 200 is never dissolved by the etching solution, but the protective layer 200 may be slightly dissolved as long as the front surface 120 and the back surface 140 of the substrate 100 are not exposed when etching is completed.

Note that in order to prevent the front surface 120 and the back surface 140 of the substrate 100 from being exposed when etching is completed, for example, a relatively thick layer is adopted as the protective layer 200, or etching time is relatively shortened.

In the present embodiment, for example, when a thin copper component having a thickness of 100 μm is manufactured, the copper substrate 100 having a thickness of 100 μm is prepared, and the protective layer 200 having a thickness of about 3 μm to 100 μm, preferably about 5 μm to 20 μm is formed on each of the front surface 120 and the back surface 140 of the substrate 100 using, for example, an organic material containing, as a main component, ethyl cellosolve also used as a photoresist material.

A method for forming the protective layer 200 is not particularly limited. The sheet-like protective layer 200 may be bonded to each of the front surface 120 and the back surface 140 of the substrate 100 using an adhesive or the like, a liquid or paste-like organic material may be applied thereto and dried, or the substrate 100 with the side surfaces 160 masked may be impregnated with a liquid or paste-like organic material and dried.

As illustrated in FIG. 1C, subsequently, the substrate 100 having the protective layer 200 formed on each of the front surface 120 and the back surface 140 is subjected to cutout processing according to a component to be manufactured, thereby manufacturing precursors 300 of a plurality of metal machined components (step S3).

Since the shape of the metal machined component itself is not the essence of the present invention, here, an example is illustrated in which cutout processing is performed by schematically assuming that a plurality of meandering metal possible components is manufactured.

As illustrated in FIG. 1D, each of the meandering precursors 300 cut out from the substrate 100 is put into a liquid tank 500 containing an etching solution such as a piranha solution, and impregnated with the etching solution to be etched (step S4).

The piranha solution is usually obtained by mixing deionized water with concentrated sulfuric acid, hydrogen peroxide, and, if necessary, a small amount of additive. A mixing amount of sulfuric acid and hydrogen peroxide with respect to deionized water is not limited, but as an example, 5% by weight of concentrated sulfuric acid (stock solution), 6% by weight of 30% hydrogen peroxide, and 1 to 2% by weight of a small amount of additive can be mixed with respect to deionized water.

The etching time is appropriately determined depending on the concentration of the etching solution, the thickness of the precursor 300 to be treated, the amount of the side surfaces 160 to be corroded, and the like. However, for example, when a thin copper component having a thickness of 100 μm is manufactured and the etching solution mixed under the conditions of the above example is used, the etching time only needs to be about three minutes.

Note that, for example, when a metal machined component made of iron or stainless steel is manufactured, the etching solution used in step S4 only needs to be obtained by mixing ferric chloride, hydrochloric acid, and, if necessary, a small amount of additive with deionized water. As an example, the etching solution can be obtained by mixing 47 baume of ferric chloride (stock solution), 15 to 25% by weight (for example, 20% by weight) of 35% hydrochloric acid, and 1 to 2% by weight of a small amount of additive with respect to deionized water.

For example, when a metal machined component made of aluminum is manufactured, the etching solution used in step S4 only needs to be phosphoric acid alone or a mixture of phosphoric acid and a sulfuric acid solution.

As illustrated in FIG. 1E, next, the precursor 300 are placed on an anode plate 720 in a liquid tank 600 containing another etching solution having a higher concentration than that of the etching solution in step S4, and the precursors 300 are impregnated with the etching solution.

The anode plate 720 is connected to a DC power supply 700 via a connection line 710, and a cathode electrode 740 is also connected to the DC power supply 700 via a connection line 730. The cathode electrode 740 is in the etching solution in the liquid tank 600.

By turning on the DC power supply 700 in this state, the precursors 300 are electrolytically polished under an applied voltage of, for example, about 1 to 10 V (step S5).

What is important here is to set a condition such that the polishing amount of each of the precursors 300 by electrolytic polishing in step S5 is smaller than the corrosion amount of each of the precursors 300 by etching in step S4. For this purpose, for example, the concentration of the former etching solution is made higher than the concentration of the latter etching solution, the former impregnation time is made longer than the latter impregnation time, or these are combined.

In the present embodiment, in step S5, an etching solution manufactured by mixing concentrated sulfuric acid (stock solution), 30% hydrogen peroxide, a required additive, and water at a ratio of about 1 to 2:1 to 2:1 to 2:3 to 7 in terms of % by weight is used, and the impregnation time of the precursors 300 is set to one to ten minutes.

Here, the conditions of the etching solution and the impregnation time in step S5 are conditions in a case where it is essential to perform not only etching but also electrolytic polishing. However, as the treatment in step S5, only etching may be performed, or only electrolytic polishing may be performed.

When only etching is performed, for example, it is possible to cope with this by increasing the concentration of the etching solution or increasing the impregnation time. Specifically, as an example, if the above condition for the impregnation time is used, an etching solution manufactured by mixing concentrated sulfuric acid, 30% hydrogen peroxide, a required additive, and deionized water at a ratio of about 1:1:1:7 in terms of % by weight can be used. On the other hand, if the above condition for the etching solution is used, the impregnation time can be set to, for example, 1 to 10 minutes.

On the other hand, when only electrolytic polishing is performed, typically, an electrolytic solution may be used without using an etching solution. However, in this case, it is possible to cope with this by increasing the impregnation time or increasing a voltage value of the applied voltage. Specifically, as an example, as the electrolytic solution, deionized water containing 5 to 15% by weight of sulfuric acid is used. If the above condition for the voltage value of the applied voltage is used, the impregnation time can be set to, for example, 30 seconds to five minutes. If the above condition for the impregnation time is used, the voltage value of the applied voltage can be set to, for example, 1 to 10 V.

As illustrated in FIG. 1F, finally, the protective layer 200 is removed from each of the electrolytically polished precursors 300 (step S6). A removing method is not particularly limited. However, for example, it may be preferable to impregnate each of the precursors 300 with a solution that corrodes the protective layer 200 but does not corrode the precursors 300 themselves. Thus, a metal machined component 400 of the present embodiment is completed.

FIG. 2 is an enlarged photograph of the vicinity of the side surface 160 of the metal machined component 400 obtained when step S6 is performed without passing through step S5 after step S4 is performed. FIG. 3 is an enlarged photograph of the side surface 160 of the precursor 300 when step S5 is performed after step S4 is performed. FIG. 4 is an enlarged photograph of the side surface 160 of the metal machined component 400 obtained when step S5 is performed after step S4 is performed, and then step S6 is performed.

First, as illustrated in FIG. 2, when step S5 is not performed, the side surface 160 has a recessed shape. In other words, both a corner between the front surface 120 and the side surface 160 and a corner between the back surface 140 and the side surface 160 are sharp. Therefore, when the corner comes into contact with a peripheral member, the peripheral member may be damaged or scraps may be generated.

As illustrated in FIG. 3, when electrolytic polishing is performed in a state where the protective layer 200 is formed on each of the front surface 120 and the back surface 140 of the substrate 100 (precursor 300), the side surface 160 is corroded as a whole, but in particular, a corner has a large amount of corrosion, and is chamfered consequently. Corrosion of about 10 μm was confirmed in the central portion of the side surface 160, and corrosion of 20 μm, which is about two times the amount of corrosion in the central portion, was confirmed in the corner of the side surface 160.

A reason why the corner of the side surface 160 is corroded more than the central portion thereof is not necessarily clear. However, it is considered that bubbles, which are reaction products, are generated one after another from a corroded portion at the time of electrolytic polishing, the bubbles are likely to stably accumulate near the central portion of the side surface 160 due to presence of both the protective layers 200, therefore the etching solution is less likely to be in contact with the central portion, while the etching solution is likely to be in contact with the corner, therefore the amount of corrosion of the corner increases, and the corner is chamfered consequently.

As illustrated in FIG. 4, in the metal machined component 400, both a corner between the front surface 120 and the side surface 160 and a corner between the back surface 140 and the side surface 160 are chamfered to form an inclined surface 180. Therefore, focusing on the side surface 160, the cross section of the side surface 160 has a protruding cross section due to presence of the inclined surface 180. Note that no processing mark is formed on the inclined surface 180 because the inclined surface 180 is not polished or the like.

In addition, the side surface 160 and the inclined surface 180 are etched and electrolytically polished, and therefore usually have relatively large surface roughness as compared with the front surface 120 and the back surface 140. Of course, by impregnating the precursor 300 with a relatively low concentration etching solution for a relatively long time, surface roughness of the side surface 160 and the inclined surface 180 is suppressed, and the side surface 160 and the inclined surface 180 may have relatively small surface roughness as compared with the front surface 120 and the back surface 140 in some cases. In any case, the surface roughness of the side surface 160 and the inclined surface 180 is different from the surface roughness of the front surface 120 and the back surface 140.

The metal machined component 400 described above can be used in a semiconductor wafer inspection apparatus or the like as a contact pin, can be used in a speaker as a metal plate, can be used as a rectifying plate having a mesh portion, or can be used in a heat sink.

### BRIEF DESCRIPTION OF DRAWINGS

FIG. 1A is a schematic manufacturing process diagram of a metal machined component according to an embodiment of the present invention.

FIG. 1B is a schematic manufacturing process diagram of the metal machined component according to the embodiment of the present invention.

FIG. 1C is a schematic manufacturing process diagram of the metal machined component according to the embodiment of the present invention.

FIG. 1D is a schematic manufacturing process diagram of the metal machined component according to the embodiment of the present invention.

FIG. 1E is a schematic manufacturing process diagram of the metal machined component according to the embodiment of the present invention.

FIG. 1F is a schematic manufacturing process diagram of the metal machined component according to the embodiment of the present invention.

FIG. 2 is an enlarged photograph of the vicinity of the side surface 160 of the metal machined component 400 obtained when step S6 is performed without passing through step S5 after step S4 is performed.

FIG. 3 is an enlarged photograph of the side surface 160 of the precursor 300 when step S5 is performed after step S4 is performed.

FIG. 4 is an enlarged photograph of the side surface 160 of the metal machined component 400 obtained when step S5 is performed after step S4 is performed, and then step S6 is performed.

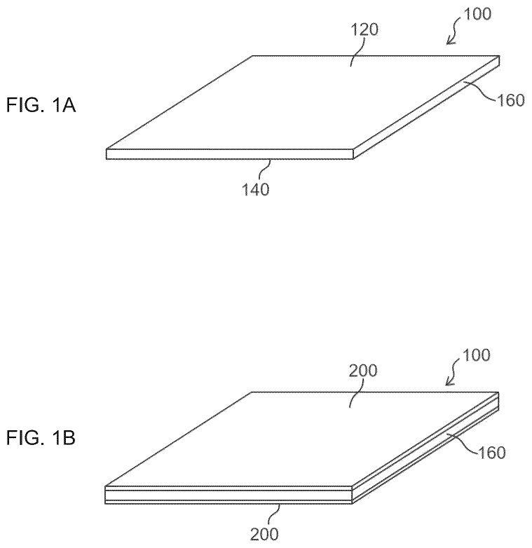

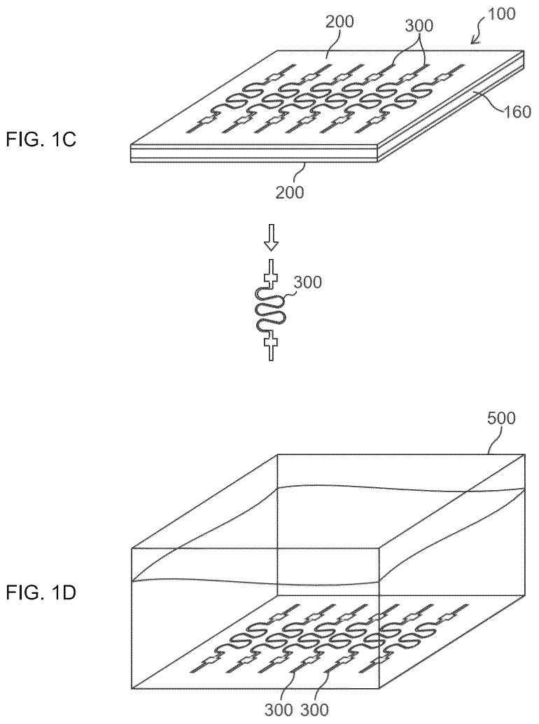

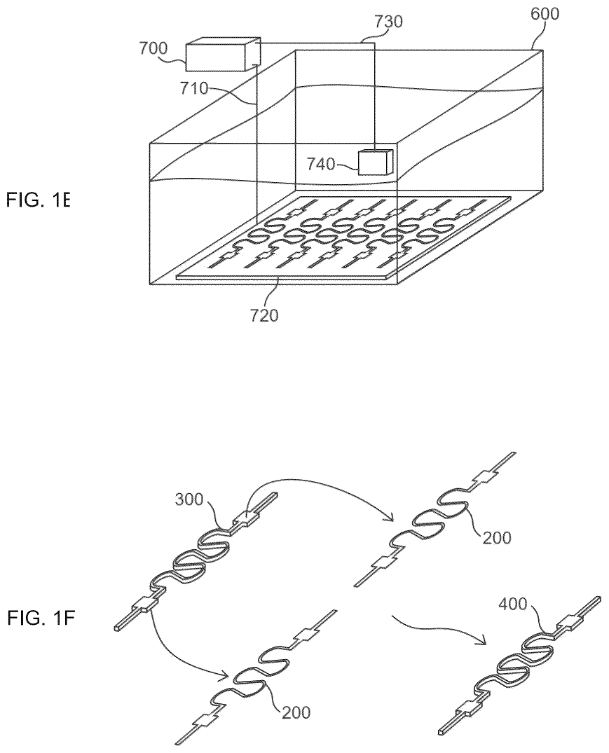

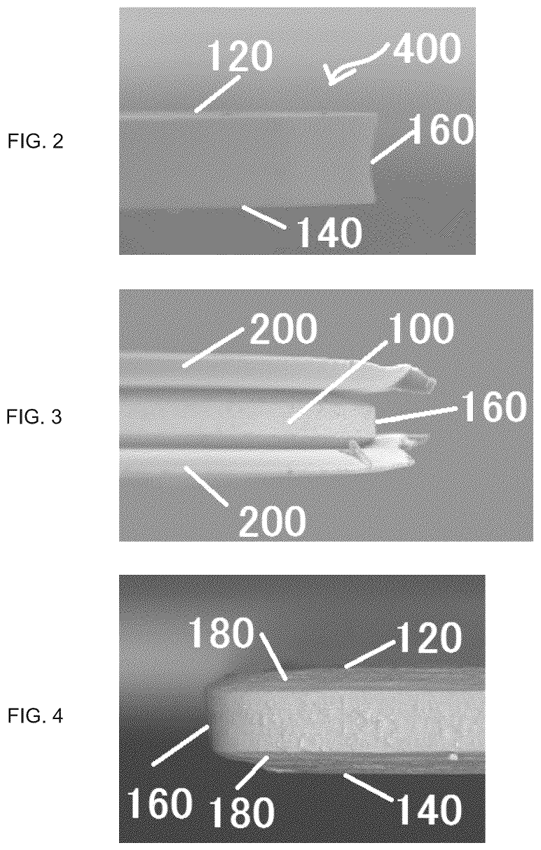

### REFERENCE SIGNS LIST

100 Substrate
120 Front surface
140 Back surface
160 Side surface
180 Inclined surface
200 Protective layer
300 Precursor
500 Liquid tank
600 Liquid tank
700 DC power supply
710 Connection line
720 Anode plate
730 Connection line
740 Cathode electrode

1. A metal machined component comprising an inclined surface having no processing mark at a corner between a front surface and a side surface and at a corner between a back surface and the side surface.

2. The metal machined component according to claim 1, wherein the side surface and the inclined surface have a surface roughness different from the front surface and the back surface.

3. The metal machined component according to claim 1, wherein the side surface has a protruding cross section.

4. A component-mounted module comprising the metal machined component according to claim 1.

5. A method for manufacturing a metal machined component, the method comprising:
forming a protective layer on each of a front surface and a back surface of a metal plate while a side surface of the metal plate is exposed;
cutting out a precursor of a component to be manufactured from the metal plate on which the protective layer is formed;
etching the cut-out precursor without removing the protective layer;
chamfering a corner between the front surface and the side surface and a corner between the back surface and the side surface of the etched precursor by an electrical or chemical treatment; and
removing the protective layer from the chamfered precursor.
